(19) United States
(12) Patent Application Publication
(10) Pub. No.: US 2026/0282620 A1
(43) Pub. Date: Sep. 17, 2026

(54) DISPLAY DEVICE INCLUDING OPTICAL FILM HAVING MULTIPLE REGIONS

(71) Applicant: LG Display Co., Ltd., Seoul (KR)

(72) Inventor: HeeJin IM, Paju-si (KR)

(21) Appl. No.: 19/679,729

(22) Filed: May 17, 2026

Related U.S. Application Data
(63) Continuation of application No. 18/218,853, filed on Jul. 6, 2023, now Pat. No. 12,677,514.

(30) Foreign Application Priority Data
Dec. 21, 2022 (KR) 10-2022-0180755

(51) Int. Cl. H10H 20/855; H10H 29/14; H10W 90/00

(52) U.S. Cl. CPC H10H 20/855; H10H 29/142; H10W 90/00

(57) ABSTRACT

A display device including a substrate provided with a plurality of subpixels, a pixel circuit disposed on the substrate, a light-emitting diode formed in each of the plurality of subpixels on the substrate and including a first electrode and a second electrode, a black matrix disposed between the plurality of subpixels on the substrate, a first connection electrode electrically connected to the first electrode and the pixel circuit, an optical layer formed above the light-emitting diodes on the substrate and including a diffusion material, and a reflective layer disposed between the substrate and the light-emitting diode.

### CROSS REFERENCE TO RELATED APPLICATIONS

This application a continuation of U.S. patent application Ser. No. 18/218,853, filed on Jul. 6, 2023, which claims priority from and the benefit of Korean Patent Application No. 10-2022-0180755, filed on Dec. 21, 2022, each of which is hereby incorporated by reference for all purposes as if fully set forth herein.

### BACKGROUND

### Field

Embodiments of the invention relate generally to a display device, and more particularly, to a display device using a light-emitting diode.

### Discussion of the Background

A display device is widely used as a display screen of a laptop computer, a tablet computer, a smart phone, a portable display device, and a portable information device display device (e.g., wearable device) in addition to a display screen of a television or a monitor. A liquid crystal display device and an organic light-emitting display device display an image by the use of thin film transistor serving as a switching element. The liquid crystal display device displays an image by the use of light irradiated from a backlight unit disposed under a liquid crystal display panel because the liquid crystal display device is not in a self-luminous manner. Since the liquid crystal display device has the backlight unit, there is a limitation in design, and luminance and response speed may be reduced. Since the organic light-emitting display device includes an organic material, the organic light-emitting display device is vulnerable to moisture, whereby reliability and lifespan thereof may be deteriorated.

Recently, research and development of a light-emitting diode display device using a micro light-emitting diode has been conducted, and the light-emitting diode display device has high quality and high reliability, whereby it is spotlighted as a next generation display device. Particularly, research is performed to realize a dual-view device through the micro light-emitting diode.

The above information disclosed in this Background section is only for understanding of the background of the inventive concepts, and, therefore, it may contain information that does not constitute prior art.

### SUMMARY

Embodiments of the invention provide a display device capable of realizing a dual view and improving a luminance.

Embodiments of the invention provide a display device capable of improving the uniformity of light distribution and the luminance of the display device while implementing a stable dual view.

Additional features of the inventive concepts will be set forth in the description which follows, and in part will be apparent from the description, or may be learned by practice of the inventive concepts.

A display device includes a substrate provided with a plurality of subpixels, a pixel circuit disposed on the substrate, a light-emitting diode formed in each of the plurality of subpixels on the substrate and including a first electrode and a second electrode, a black matrix disposed between the plurality of subpixels on the substrate, a first connection electrode connected to the first electrode and the pixel circuit, an optical layer formed above the light-emitting diodes on the substrate and including a diffusion material and a reflective layer disposed between the substrate and the light-emitting diode.

The reflective layer may be connected to the pixel circuit and the first connection electrode.

The display device may further include an adhesive layer disposed between the reflective layer and the light-emitting diode.

The pixel circuit may include a TFT.

The TFT may include an active layer, a gate electrode, a source electrode, and a drain electrode.

The first connection electrode may be connected to the reflective layer through a contact hole.

The black matrix may be disposed in the contact hole.

The display device may further include a first planarization layer disposed on the black matrix and the light-emitting diode.

The first planarization layer may be disposed between the light-emitting diode and the optical layer.

The display device may further include a second planarization layer surrounding the light-emitting diode.

The display device may further include a third planarization layer disposed on the second planarization layer to surround the light-emitting diode.

The diffusion material may be in the form of bead formed of resin.

The diffusion material may be in the form of bead formed of one or more of polymethyl methacrylate PMMA, polybutyl methacrylate PBMA, polystyrene PS.

The display device may further include a light shielding layer disposed below the pixel circuit on the substrate.

The display device may further include a buffer layer disposed on the substrate and the light shielding layer.

The display device may further include a second connection electrode connecting the second electrode to a first power line.

The substrate may be formed of glass, metal foils or plastic.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIGS. 1A and 1B are plan views illustrating a display device according to an embodiment of the invention;

FIG. 2 is a cross-sectional view illustrating a display device according to an embodiment of the invention.

FIG. 3 is a cross-sectional view illustrating a display device according to another embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

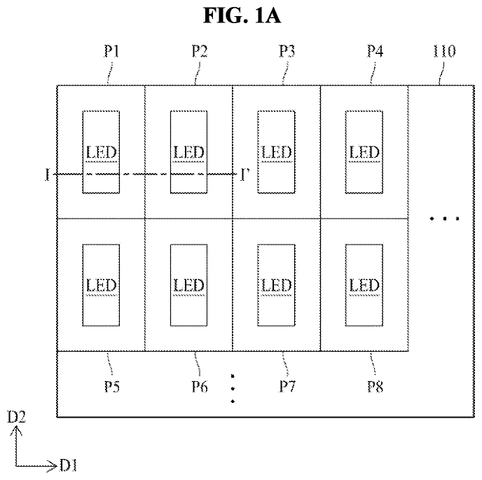

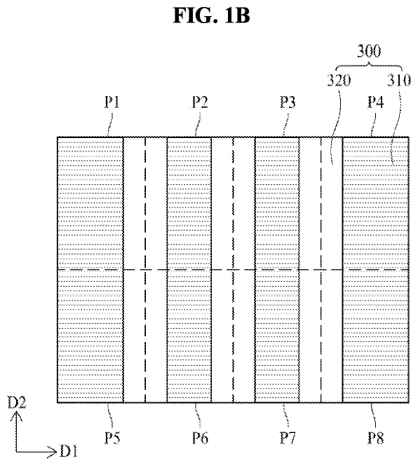

FIGS. 1A and 1B are plan views illustrating a display device according to an embodiment of the invention. All the components of each display device according to embodiments of the invention are operatively coupled and configured.

Referring to FIG. 1A, a substrate 110 may include a plurality of subpixels P1-P8. The plurality of subpixels P1-P8 may be formed in a matrix type along a first direction D1 and a second direction D2 perpendicular to the first direction D1. Each of the plurality of subpixels P1-P8 may include a light-emitting diode LED. The light-emitting diode LED is formed on the substrate 110 and is configured to emit light.

Referring to FIG. 1B, an optical film 300 may be formed on the light-emitting diode LED, and may cover the entire substrate 110. The optical film 300 may include first and second regions 310 and 320. The first and second regions 310 and 320 may be alternately formed along the first direction D1. In addition, each of the first and second regions 310 and 320 may have a shape extending along the second direction D2. The first region 310 may include a light-blocking material (for example, the first region 310 may include a black dye) and may be formed to overlap with the light-emitting diode LED. Also, the second region 320 may include a transparent insulating material (for example, Polyethylene terephthalate (PET), Polyethylene naphthalate (PEN), Poly(methyl methacrylate) (PMMA), Cyclo-olefin polymers (COP) or cyclo-olefin copolymers (COC)), and may be formed in a boundary region of the subpixel P. However, embodiments of the invention are not limited thereto.

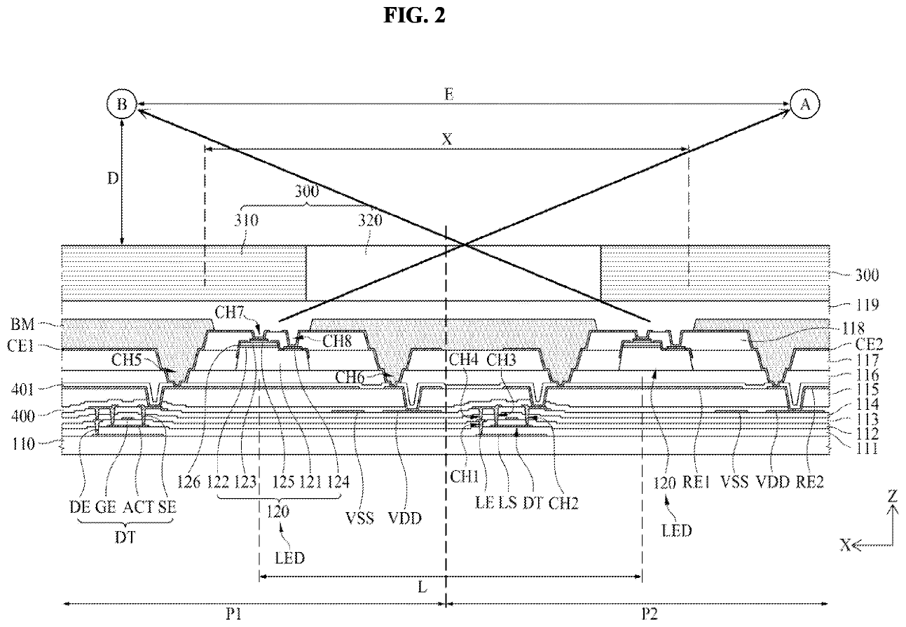

FIG. 2 is a cross sectional view illustrating the display device according to an embodiment of the invention. FIG. 2 illustrates the first and second subpixels P1 and P2 adjacent to each other.

Referring to FIG. 2, the display device includes the substrate 110, a buffer layer 111, a gate insulating layer 112, a first insulating interlayer 113, a second insulating interlayer 114, a third insulating interlayer 400, a first planarization layer 115, a fourth insulating interlayer 401, an adhesive layer 116, a second planarization layer 117, a third planarization layer 118, a fourth planarization layer 119, the optical film 300, a driving transistor DT, the light-emitting diode LED, a first reflective electrode RE1, a second reflective electrode RE2, a first connection electrode CE1, a second connection electrode CE2, a light shielding layer LS, an auxiliary electrode LE, and a bank BM, but not limited thereto.

The substrate 110 may be formed of glass, metal foils or plastic (e.g. Polymers such as PET or PEN), but not limited thereto. The display device according to an embodiment of the invention may be configured by a top emission type in which emitted light is emitted toward an upper portion, a bottom emission type, or a dual emission type. Therefore, a transparent material as well as an opaque material may be used as a material for the substrate 110 in top emission type display device. In the bottom emission type, the light emitted from the pixel array layer may be irradiated onto a rearward region behind the substrate to allow an image to be displayed, thus, a transparent material may be used as a material for the substrate 110.

The light shielding layer LS is formed on the substrate 110 and may be formed in each of the first and second subpixels P1 and P2. The light shielding layer LS may block light incident on the transistor from a lower portion of the substrate 110 to reduce or minimize leakage current. For example, the light shielding layer LS blocks light incident from a lower portion of the substrate 110 to an active layer ACT of the driving transistor DT, thereby reducing or minimizing a leakage current.

The buffer layer 111 may be formed on the substrate 110 and the light shielding layer LS. The buffer layer 111 may reduce penetration of moisture or impurities through the substrate 110. For example, the buffer layer 111 may be composed of a single layer or multiple layers of silicon oxide (SiOx) or silicon nitride (SiNx), but not limited thereto. However, the buffer layer 111 may be omitted depending on the type of the substrate 110 or the type of transistor, but not limited thereto.

The driving transistor DT may be formed on the buffer layer 111. The driving transistor DT may include the active layer ACT, a gate electrode GE, a source electrode SE, and a drain electrode DE.

The active layer ACT may be formed on the buffer layer 111. The active layer ACT may be formed of a semiconductor material such as oxide semiconductor, amorphous silicon, and polysilicon, but not limited thereto. The active layer ACT may be a polycrystalline semiconductor. The polycrystalline semiconductor may be formed of a low temperature poly silicon (LTPS) having a high mobility, but is not limited thereto. For example, the active layer ACT may be formed of an oxide semiconductor or includes the oxide semiconductor, for example, the active layer ACT may be formed of one of indium gallium zinc oxide (IGZO), indium zinc oxide (IZO), indium gallium tin oxide (IGTO), and indium gallium oxide (IGO), but is not limited thereto. Alternatively, the active layer ACT may be formed of various organic semiconductors such as amorphous silicon (a-Si), polycrystalline silicon (poly-Si), or pentacene, etc., but is not limited thereto.

The gate insulating layer 112 may be formed on the active layer ACT. The gate insulating layer 112 is an insulating layer for insulating the active layer ACT and the gate electrode GE from each other, and may be composed of a single layer or multilayers of silicon oxide (SiOx) or silicon nitride (SiNx), but not limited thereto.

The gate electrode GE may be formed on the gate insulating layer 112 and may be electrically connected to the scan line. The gate electrode GE may be formed of a conductive material, for example, copper Cu, aluminum Al, molybdenum Mo, nickel Ni, titanium Ti, chromium Cr, or an alloy thereof, but not limited thereto.

The first and second insulating interlayers 113 and 114 may be formed on the gate electrode GE. Through a contact hole formed in each of the first and second insulating interlayers 113 and 114, each of source electrode SE and the drain electrode DE may be electrically connected to the active layer ACT. The first and second insulating interlayers 113 and 114 are insulating layers for protecting configurations disposed below the first and second insulating interlayers 113 and 114 (for example, components disposed below the first and second insulating interlayers 113 and 114), and may be composed of a single layer or multilayers of silicon oxide (SiOx) or silicon nitride (SiNx), but not limited thereto.

The source electrode SE and drain electrode DE electrically connected to the active layer ACT are disposed on the second insulating interlayer 114. The source electrode SE and the drain electrode DE may be formed of a conductive material, for example, copper Cu, aluminum Al, molybdenum Mo, nickel Ni, titanium Ti, chromium Cr, or an alloy thereof, but not limited thereto.

Meanwhile, as shown in FIG. 2, the first and second insulating interlayers 113 and 114, more particularly, a plurality of insulating layers are disposed between each of the gate electrode GE, the source electrode SE and the drain electrode DE, but only one insulating layer or N insulating layers (e.g., N is an integer more than 2) may be disposed between each of the gate electrode GE, the source electrode SE and the drain electrode DE, for example, the first insulating interlayers 113 or the second insulating interlayer 114 is disposed between each of the gate electrode GE, the source electrode SE and the drain electrode DE, or three or more insulating interlayers are disposed between each of the gate electrode GE, the source electrode SE and the drain electrode DE, but not limited thereto.

In particular, as shown in FIG. 2, when the plurality of insulating layers such as the first and second insulating interlayers 113 and 114 are disposed between each of the gate electrode GE, the source electrode SE and the drain electrode DE, an electrode may be additionally formed between the first and second insulating interlayers 113 and 114, and the additionally formed electrode may form a capacitor element different from that of element disposed below the first insulating interlayer 113 or disposed above the second insulating interlayer 114.

The auxiliary electrode LE may be formed on the gate insulating layer 112. The auxiliary electrode LE may electrically connect the light shielding layer LS to any one of the source electrode SE and the drain electrode DE. Accordingly, since the light shielding layer LS does not operate as a floating gate by the source electrode SE or the drain electrode DE, it may be possible to reduce or minimize a change in a threshold voltage of the driving transistor DT caused by the floated light shielding layer LS. In FIG. 2, the light shielding layer LS is connected to the drain electrode DE through a first contact hole CH1 passing through the buffer layer 111 and the gate insulating layer 112 and a fourth contact hole CH4 passing through the first and second insulating interlayers 113 and 114. However, the light shielding layer LS may also be connected to the source electrode SE, but not limited thereto.

The source electrode SE, the drain electrode DE, a first power line VDD, and a second power line VSS may be formed on the second insulating interlayer 114. The first power line VDD is electrically connected to the light-emitting diode LED together with the driving transistor DT, to emit light of the light-emitting diode LED. The first power line VDD and the second power line VSS may be formed of a conductive material, for example, copper Cu, aluminum Al, molybdenum Mo, nickel Ni, titanium Ti, chromium Cr, or an alloy thereof, but not limited thereto.

The third insulating interlayer 400 may be formed on the driving transistor DT, the first power line VDD, and the second power line VSS. The third insulating interlayer 400 is an insulating layer for protecting configurations disposed under the third insulating interlayer 400 (for example, components disposed under the third insulating interlayer 400), and may be composed of a single layer or multilayers of silicon oxide (SiOx) or silicon nitride (SiNx), but not limited thereto.

The first planarization layer 115 may be formed on the third insulating interlayer 400. The first planarization layer 115 may planarize an upper portion of the substrate 110 on which the driving transistor DT is disposed. The first planarization layer 115 may be formed of a single layer or multilayers, and may be formed of, for example, a photoresist or acryl-based organic material, but not limited thereto.

The first and second reflective electrodes RE1 and RE2 may be formed on the first planarization layer 115 and may be arranged to be spaced apart from each other. The first and second reflective electrodes RE1 and RE2 electrically connect the light-emitting diode LED to the first power line VDD and the driving transistor DT and serve as a reflector for reflecting the light emitted from the light-emitting diode LED to the upper portion of the light-emitting diode LED. The first and second reflective electrodes RE1 and RE2 are formed of a conductive material having high reflectivity, and may reflect the light emitted from the light-emitting diode LED toward the upper portion of the light-emitting diode LED.

The first reflective electrode RE1 may electrically connect the driving transistor DT and the light-emitting diode LED. The first reflective electrode RE1 may be connected to the source electrode SE or the drain electrode DE of the driving transistor DT through a contact hole formed in the first planarization layer 115. The first reflective electrode RE1 may be electrically connected to the first electrode 124 and the first semiconductor layer 121 of the light-emitting diode LED through the first connection electrode CE1 to be described later, but not limited thereto.

The second reflective electrode RE2 may electrically connect the first power line VDD and the light-emitting diode LED. The second reflective electrode RE2 is connected to the first power line VDD through a sixth contact hole CH6 formed in the first planarization layer 115 and may be electrically connected to the second electrode 125 and the second semiconductor layer 123 of the light-emitting diode LED through the second connection electrode CE2 to be described later, but not limited thereto.

The fourth insulating interlayer 401 may be formed on the first and second reflective electrodes RE1 and RE2. The fourth insulating interlayer 401 is an insulating layer for protecting configurations disposed under the fourth insulating interlayer 401 (for example, components disposed under the fourth insulating interlayer 401), and may be composed of a single layer or multilayers of silicon oxide (SiOx) or silicon nitride (SiNx), but not limited thereto.

An adhesive layer 116 may be formed on the fourth insulating interlayer 401. The adhesive layer 116 is coated on the entire surface of the substrate 110, to fix the light-emitting diode LED disposed on the adhesive layer 116. For example, the adhesive layer 116 may be selected from any one or more of adhesive polymer, epoxy resist, UV resin, polyimide-based material, acrylate-based material, urethane-based material, or polydimethylsiloxane-based PDMS material, but not limited thereto.

The plurality of light-emitting diodes LEDs is formed on the adhesive layer 116, and may be formed in each of the first and second subpixels P1 and P2. The plurality of light-emitting diodes LEDs may include light-emitting diodes LED for emitting red light, green light, blue light, and the like, as elements for emitting light by a current, and may implement light of various colors including white by a combination thereof. For example, the plurality of light-emitting diodes LEDs may be light-emitting diodes LEDs or micro LEDs, but not limited thereto. The light-emitting diode LED may include a first semiconductor layer 121, a light-emitting layer 122, a second semiconductor layer 123, a first electrode 124, a second electrode 125, and an encapsulation film 126 or encapsulation layer 126.

The first semiconductor layer 121 is formed on the adhesive layer 116 and may provide holes to the light-emitting layer 122. The first semiconductor layer 121 may be formed of a p-GaN-based semiconductor material such as GaN, AlGaN, InGaN, and AlInGaN, without being limited thereto. Also, impurities used for doping of the first semiconductor layer 121 may be Mg, Zn, Be, or the like, but not limited thereto.

The light-emitting layer 122 is formed on the first semiconductor layer 121 and may be the light-emitting layer for emitting light. The light-emitting layer 122 may have a multi-quantum well MQW structure having a well layer and a barrier layer having a band gap higher than that of the well layer. For example, the light-emitting layer 122 may have a multi-quantum well structure of InGaN/GaN, but not limited thereto.

The second semiconductor layer 123 is formed on the light-emitting layer 122 and may provide electrons to the light-emitting layer 122. The second semiconductor layer 123 may be formed of an n-GaN-based semiconductor material such as GaN, AlGaN, InGaN, and AlInGaN, without being limited thereto. Also, impurities used for doping of the second semiconductor layer 123 may be Si, Ge, Se, Te, C, or the like, but not limited thereto.

The light-emitting diode LED is manufactured by sequentially stacking the first semiconductor layer 121, the light-emitting layer 122, and the second semiconductor layer 123, and then etching a predetermined portion thereof to form the first electrode 124 and the second electrode 125. The etched portion is provided to space the first electrode 124 and the second electrode 125 apart from each other, and a predetermined portion may be etched to expose a portion of the first semiconductor layer 121. More particularly, the first electrode 124 and the second electrode 125 may be formed at different heights.

Then, the encapsulation film 126 or encapsulation layer 126 (not shown) may be formed to surround the first semiconductor layer 121, the light-emitting layer 122, the second semiconductor layer 123, the first electrode 124, and the second electrode 125. The encapsulation film 126 or encapsulation layer 126 is formed of an insulating material and is configured to protect the first semiconductor layer 121, the light-emitting layer 122, and the second semiconductor layer 123. A contact hole exposing the first electrode 124 and the second electrode 125 is formed in the encapsulation film 126 or encapsulation layer 126, whereby the first connection electrode CE1 and the second connection electrode CE2 may be electrically connected to the first electrode 124 and the second electrode 125. Each of the first and second electrodes 124 and 125 may comprise a metal material such as Au, W, Pt, Si, Ir, Ag, Cu, Ni, Ti, and Cr, or an alloy thereof. Alternatively, each of the first and second electrodes 124 and 125 may include a transparent conductive material such as ITO indium tin oxide and IZO indium zinc oxide, without being limited thereto.

The second and third planarization layers 117 and 118 may be formed on the plurality of light-emitting diodes LEDs. The second and third planarization layers 117 and 118 are arranged to cover the plurality of light-emitting diodes LEDs, to fix and protect the plurality of light-emitting diodes LEDs. The second and third planarization layers 117 and 118 may be composed of a single layer or multiple layers, for example, photoresist or acryl-based organic material, but not limited thereto. Meanwhile, the second and third planarization layers 117 and 118 may be disposed to cover the plurality of light-emitting diodes LEDs. For example, the planarization layer covering the plurality of light-emitting diodes LEDs may be formed as a single layer or n-layers (e.g., n is an integer greater than 2), but not limited thereto. In addition, the third planarization layer 118 may be disposed only in an area adjacent to the light-emitting diode LED.

After deposition of the third planarization layer 118, the first and second connection electrodes CE1 and CE2 may be formed.

The first connection electrode CE1 is disposed in each of the first and second subpixels P1 and P2 and is configured to electrically connect the light-emitting diode LED and the driving transistor DT to each other. The first connection electrode CE1 may be connected to the first reflective electrode RE1 through a contact hole passing through insulating layers, for example, the first connection electrode CE1 may be connected to the first reflective electrode RE1 through a contact hole formed in the third planarization layer 118, the second planarization layer 117, and the adhesive layer 116, but not limited thereto. Accordingly, the first connection electrode CE1 may be electrically connected to any one of the source electrode SE and the drain electrode DE of the driving transistor DT through the first reflective electrode RE1. The first connection electrode CE1 may be connected to an n-type electrode in each of the plurality of light-emitting diodes LEDs through a contact hole formed in the third planarization layer 118. Therefore, the first connection electrode CE1 may electrically connect the driving transistor DT to the n-type electrode and the n-type semiconductor layer of the plurality of light-emitting diodes LEDs.

The second connection electrode CE2 may electrically connect the light-emitting diode LED to the first power line VDD. The second connection electrode CE2 may be connected to the second reflective electrode RE2 through a contact hole passing through insulating layers, for example, the second connection electrode CE2 may be connected to the second reflective electrode RE2 through a contact hole formed in the third planarization layer 118, the second planarization layer 117, and the adhesive layer 116, but not limited thereto. Thus, the second connection electrode CE2 may be electrically connected to the first power line VDD through the second reflective electrode RE2. The second connection electrode CE2 may be connected to a p-type electrode in each of the plurality of light-emitting diodes LEDs through a contact hole formed in the third planarization layer 118. Therefore, the second connection electrode CE2 may electrically connect the first power line VDD to the p-type electrode and the p-type semiconductor layer of the plurality of light-emitting diodes LEDs.

The first connection electrode CE1 for connecting the driving transistor DT disposed in each of the first and second subpixels P1 and P2 to the light-emitting diode LED may be individually disposed in each of the first and second subpixels P1 and P2. The second connection electrodes CE2 disposed in each of the first and second subpixels P1 and P2 and configured to connect the first power line VDD and the light-emitting diode LED may be connected to each other. More particularly, since the power voltage of the first power line VDD is commonly applied to the plurality of light-emitting diodes LEDs of the first and second subpixels P1 and P2, a single second connection electrode CE2 may be disposed in the first and second subpixels P1 and P2.

The bank BM is formed on the third planarization layer 118 and is configured to define a light-emitting area. The bank BM may be formed of an inorganic insulating material or an organic insulating material. Also, the bank BM may be formed of an organic film such as acryl resin, epoxy resin, phenolic resin, polyamide resin, polyimide resin, and the like, and may include a black material for absorbing light, but not limited thereto.

The fourth planarization layer 119 may be formed on the bank BM and the light-emitting diode LED. The fourth planarization layer 119 is formed to cover the entire surface of the substrate 110, to planarize the upper portion of the light-emitting diode LED. The fourth planarization layer 119 may be formed of an inorganic insulating material such as silicon oxide (SiOx) or silicon nitride (SiNx), without being limited thereto. Alternatively, the fourth planarization layer 119 may include an organic insulating material such as acryl resin, epoxy resin, phenolic resin, polyamide resin, and polyimide resin, but not limited thereto. Alternatively, the fourth planarization layer 119 may be formed as more layers.

The optical film 300 is formed on the fourth planarization layer 119 and is configured to cover the entire substrate 110. The optical film 300 may include the first and second regions 310 and 320.

The first region 310 may include a light-blocking material. For example, the first region 310 may include a black dye. Also, the first region 310 may be overlapped with the light-emitting diode LED in each of the first and second subpixels P1 and P2.

In addition, the second region 320 may include a transparent insulating material. For example, the second region 320 may include an inorganic insulating material such as silicon oxide (SiOx) and silicon nitride (SiNx). Alternatively, the second region 320 may include an organic insulating material such as acryl resin, epoxy resin, phenolic resin, polyamide resin, and polyimide resin, but not limited thereto. Also, the second region 320 may be formed between the adjacent first regions 310. More particularly, the second region 320 may be formed in the boundary area of the first and second subpixels P1 and P2.

As described above, since the first region 310 blocks light, an image of the display device may be displayed by the light transmitted through the second region 320. More particularly, through the second region 320, the light generated from the light-emitting diode LED may be emitted in the direction having an inclination relative to the upper surface of the optical film 300. For example, the light generated from the light-emitting diode LED of the first subpixel P1 may be emitted to a first viewing area A, and the light generated from the light-emitting diode LED of the second subpixel P2 may be emitted to a second viewing area B, but not limited thereto. That is, the first and second subpixels P1 and P2 may emit light in different directions.

In this case, when the first and second subpixels P1 and P2 display different images, the images displayed in the first and second viewing areas A and B may be different from each other. Therefore, since two or more images may be displayed on one display device, it may be possible to provide a dual-view display device using the light-emitting diode LED according to embodiments of the invention.

In this case, when the distance from the center of the first region 310 formed in the first subpixel P1 to the center of the first region 310 formed in the second subpixel P2 is X, the value of X may follow Equation 1. In this case, ‘L’ may be the distance between the centers of the first and second subpixels P1 and P2, ‘v’ may be the number of images, and ‘E’ may be the distance between the first and second viewing areas A and B. Referring to FIG. 2, which discloses a dual view, the value of ‘v’ may be 2, but not limited thereto, and the value of ‘v’ may also be >3. In addition, the width of the second region 320 may be about 0.5 times the X, but not limited thereto.

$$X = \frac{v}{\frac{1}{L} + \frac{1}{E}} \qquad Equation 1$$

In addition, when the distance from the light-emitting diode LED to the upper surface of the optical film 300 is Y, the value of Y may follow Equation 2. Herein, ‘n’ may be a refractive index of the material constituting the fourth planarization layer 119, and ‘D’ may be the distance from the upper surface of the optical film 300 to the first viewing area A and the second viewing area B. For example, the value of ‘n’ may be 1.5, but not limited thereto.

$$Y = \frac{L \times n \times D}{E} \qquad Equation 2$$

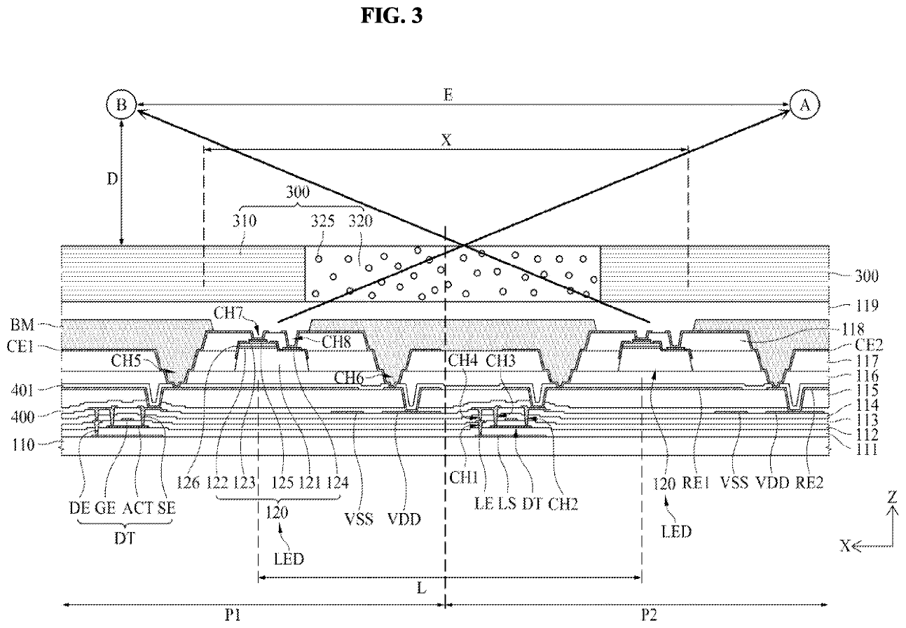

FIG. 3 is a cross sectional view of a display device according to another embodiment of the invention.

Compared with FIG. 2, FIG. 3 discloses substantially the same structure except for the structure of the optical film 300. Therefore, the same elements as those of the display device shown in FIG. 2 are denoted by the same reference numerals, and repeated descriptions thereof are omitted.

Referring to FIG. 3, the optical film 300 may include first and second regions 310 and 320.

As described above, the first region 310 may include a light-blocking material. For example, the first region 310 may include a black dye. Also, the first region 310 may be formed to overlap with the light-emitting diode LED in each of the first and second subpixels P1 and P2. In addition, the second region 320 may include a transparent insulating material. For example, the second region 320 may include an inorganic insulating material such as silicon oxide (SiOx) and silicon nitride (SiNx). Alternatively, the second region 320 may include an organic insulating material such as acryl resin, epoxy resin, phenolic resin, polyamide resin, and polyimide resin, but not limited thereto. In addition, the second region 320 may be formed between the adjacent first regions 310. More particularly, the second region 320 may be formed in the boundary area of the first and second subpixels P1 and P2.

The second region 320 may further include a diffusion material 325. Accordingly, light passing through the second region 320 may be diffused. The diffusion material 325 may be in the form of bead formed of resin such as polymethyl methacrylate PMMA, polybutyl methacrylate PBMA, polystyrene PS, or the like. The transmittance of the second region 320 may be 90% or more, but not limited thereto.

When a user watches an image at a position adjacent to the second region 320 than the first region 310, there is a possibility of a blurry image due to the overlapping of some of the light emitted from the first and second subpixels P1 and P2. However, embodiments of the invention may distribute light passing through the second region 320 since the diffusion material 325 is provided in the second region 320. Accordingly, it may be possible to reduce the overlap of light emitted from the first and second subpixels P1 and P2. Therefore, the present disclosure may further improve the uniformity of light distribution and the luminance of the display device while implementing a stable dual view. According to the embodiments of the invention, it may be possible to realize the dual view and to improve the luminance of the display device by the optical film including the light-blocking material and the diffusion material.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a substrate provided with a plurality of subpixels;
a pixel circuit disposed on the substrate;
a light-emitting diode formed in each of the plurality of subpixels on the substrate and including a first electrode and a second electrode;
a black matrix disposed between the plurality of subpixels on the substrate;
a first connection electrode connected to the first electrode and the pixel circuit;
an optical layer formed above the light-emitting diodes on the substrate and including a diffusion material; and
a reflective layer disposed between the substrate and the light-emitting diode.

2. The display device according to claim 1, wherein the reflective layer is connected to the pixel circuit and the first connection electrode.

3. The display device according to claim 1, further comprising an adhesive layer disposed between the reflective layer and the light-emitting diode.

4. The display device according to claim 1, wherein the pixel circuit includes a TFT.

5. The display device according to claim 4, wherein the TFT includes an active layer, a gate electrode, a source electrode, and a drain electrode.

6. The display device according to claim 1, wherein the first connection electrode is connected to the reflective layer through a contact hole.

7. The display device according to claim 6, wherein the black matrix is disposed in the contact hole.

8. The display device according to claim 1, further comprising a first planarization layer disposed on the black matrix and the light-emitting diode.

9. The display device according to claim 8, wherein the first planarization layer is disposed between the light-emitting diode and the optical layer.

10. The display device according to claim 8, further comprising a second planarization layer surrounding the light-emitting diode.

11. The display device according to claim 10, further comprising a third planarization layer disposed on the second planarization layer to surround the light-emitting diode.

12. The display device according to claim 1, wherein the diffusion material is in the form of bead made of resin.

13. The display device according to claim 12, wherein the diffusion material is in the form of bead made of one or more of polymethyl methacrylate PMMA, polybutyl methacrylate PBMA, polystyrene PS.

14. The display device according to claim 1, further comprising a light shielding layer formed below the pixel circuit on the substrate.

15. The display device according to claim 14, further comprising a buffer layer formed on the substrate and the light shielding layer.

16. The display device according to claim 1, further comprising a second connection electrode connecting the second electrode to a first power line.

17. The display device according to claim 1, wherein the substrate is formed of glass, metal foils or plastic.
